(19) United States
(12) Patent Application Publication
(10) Pub. No.: US 2002/0072155 A1
(43) Pub. Date: Jun. 13, 2002

(54) Method of fabricating a DRAM unit

(76) Inventors: Chih-Cheng Liu, Pan-Chiao City (TW); De-Yuan Wu, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/732,295

(22) Filed: Dec. 8, 2000

(51) Int. Cl. H01L 21/84; H01L 21/00

(52) U.S. Cl. 438/151; 438/164; 438/152

(57) ABSTRACT

The present invention provides a method of making a dynamic random access memory (DRAM) unit. The method begins by providing a silicon-on-insulator substrate (SOI), the SOI substrate comprising a first isolation layer formed on a substrate, and a first silicon layer of a first conductive type formed on the first isolation layer. An oxygen ion implantation process is then performed to form a second isolation layer within the first silicon layer, the second isolation layer dividing the first silicon layer into an upper and a lower layer, or a second and a third silicon layer, respectively. Next, a shallow trench isolation is formed in the second silicon layer, as well as an active area isolated by the shallow trench isolation with the second isolation layer on the second silicon layer. Finally, a metal-oxide-semiconductor field-effect-transistor (MOSFET) is formed in the active area in the second silicon layer.

### BACKGROUND OF THE INVENTION

1. Field of the Invention

The present invention relates to a method of making a silicon-on-insulator(SOI) device, and more particularly, to a method of making a metal-oxide-semiconductor field-effect-transistor (MOSFET) on a SOI substrate with high threshold voltage and low junction leakage.

2. Description of the Prior Art

A SOI substrate is normally formed by the use of a separation by implantation oxygen(SIMOX) method to form a silicon dioxide isolation layer beneath the surface of a silicon substrate, or by the use of a smart cut process to form a SOI substrate with a single crystal layer, an isolation layer and a silicon substrate. Generally, the MOSFET formed on the SOI substrate is installed in the single crystal layer separated from the silicon substrate by the silicon dioxide isolation layer. The insulation provided by the isolation layer prevents both the occurrence of the latch up phenomenon of electrical devices as well as electrical breakdown of the MOSFET.

Based on the above-mentioned advantages, the SOI substrate is increasingly being applied to many semiconductor products, such as dynamic random access memory (DRAM), erasable programmable read only memory (EPROM), electrically erasable programmable read only memory (EEPROM), flash memory, power IC and other consumer IC parts. Thus, due to the extensive application of the SOI device, problems occurring from its use need to be resolved.

In the prior art, the installation of a DRAM unit on a SOI substrate requires the application of a bias voltage to a silicon layer of the SOI substrate to control both the threshold voltage (Vₜ) and the sub-threshold voltage of a gate channel. Control of both the threshold voltages allows the gate channel to remain in a floating state during standby mode. Furthermore, if a constant high threshold voltage (high Vₜ) is to be maintained, the use of a high dosage Vₜ adjusting implantation process is usually required. However, the continued decrease in the size of a device results in both higher junction leakage and lower gate electrode breakage voltage during high dosage implantation.

Thus, several methods have been developed to resolve the above-mentioned problems. For example, in U.S. Pat. No. 6,088,260, Choi and Jin Hyeok disclose a method of forming a SOI substrate by the addition of a doped polysilicon layer, acting as a plate electrode, between two substrates. Choi and Jin Hyeok then utilize the SOI substrate with the plate electrode to produce a DRAM device without a piled capacitor structure. Although the method disclosed by Choi and Hyeok can produce a better DRAM device, the above-mentioned problem remain unresolved.

### SUMMARY OF THE INVENTION

It is an object of the present invention to provide a method of making a SOI device with back gate electrode control to obtain improved channel control.

Another object according to the present invention is to provide a method of making the SOI device with high threshold voltage and low junction leakage.

A further object according to the present invention is to provide a method of making a DRAM device on the SOI substrate, the latter formed by the SIMOX process, and the former having characteristics of high threshold voltage and low junction leakage.

In one of the preferred embodiments according to the present invention, a SOI substrate is first provided, the SOI substrate comprising a first isolation layer formed on a substrate, and a first silicon layer of a first conductive type formed on the first isolation layer. Then, an oxygen ion implantation process is used to form a second isolation layer on the first silicon layer, the first silicon layer divided into an upper and lower layer, the second silicon layer and the third silicon layer, respectively. The second isolation layer is formed on the second silicon layer and then a shallow trench isolation is formed in the second silicon layer with at least one active area isolated by the shallow trench isolation. Finally, a single MOSFET is formed on the second silicon layer of the active area, the MOSFET comprising a gate electrode installed on the second silicon layer, and a source and drain electrode of a second conductive type formed on both sides of the gate electrode in the second silicon layer.

The third silicon layer connects to a biased power supply by a well pick-up of the first conductive type, and functions in lifting the threshold voltage of the gate to obtain improved performance in channel control. The result is a DRAM device of the present invention with characteristics of high threshold voltage and low junction leakage.

These and other objectives of the present invention will no doubt become obvious to those of ordinary skill in the art after having read the following detailed description of the preferred embodiment which is illustrated in the various figures and drawings.

### BRIEF DESCRIPTION OF THE DRAWINGS

FIG. 1 to FIG. 6 is the cross sectional schematic diagrams of making a DRAM unit on the SOI substrate according to the present invention.

### DETAILED DESCRIPTION OF THE PREFERRED EMBODIMENT

Please refer to FIG. 1 to FIG. 6. FIG. 1 to FIG. 6 are the cross sectional schematic diagrams of making a DRAM unit on a SOI substrate 100. As shown in FIG. 1, a SOI substrate 100 is first provided. The SOI substrate 100 comprises a silicon substrate 103, a buried oxide layer 102 installed on the silicon substrate 103, and a P type silicon layer 101 installed on the buried oxide layer 102, respectively. In the preferred embodiment according to the present invention, the SOI substrate 100 is a commercial product formed by the conventional SIMOX method, with the P type silicon layer 101 thickness of approximately 3 micrometers. The main goal of the present invention is not to give a detailed description of the making of the SOI substrate 100 and so will not be explained further. Other methods of manufacturing the SOI substrate 100 are referred to in the U.S. Pat. Nos. 5,665,631, 5,753,353 or 6,074,928.

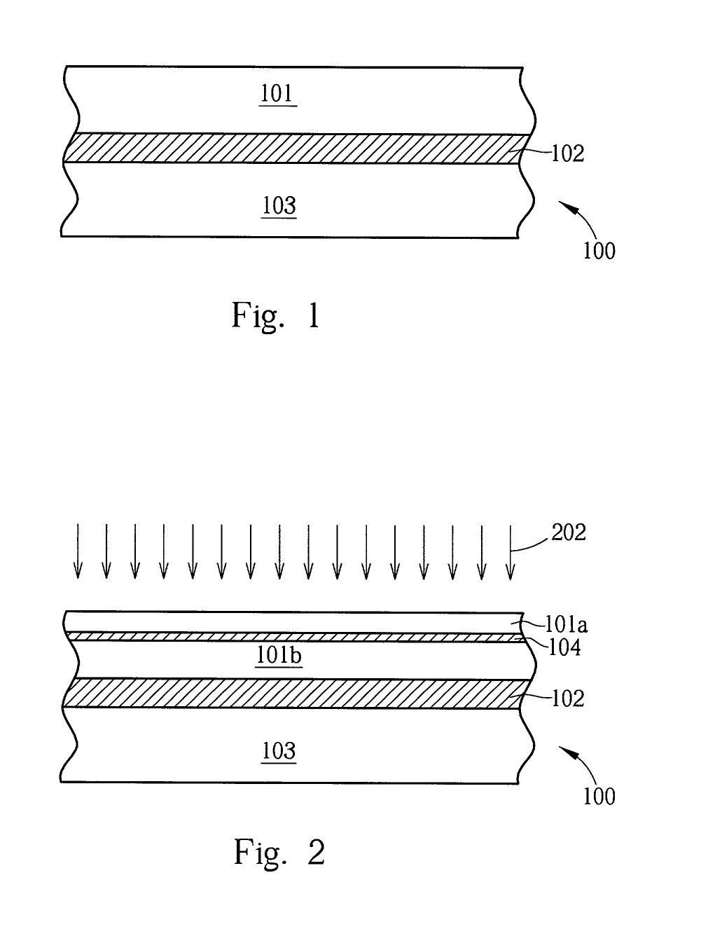

As shown in FIG. 2, an oxygen ion implantation process 202 is later used to form a silicon dioxide isolation layer 104 within the P type silicon layer 101. In the oxygen ion implantation process 202, the energy of oxygen ions is 100 KeV with a dosage of approximately 3.6E17 ions/cm². In the preferred embodiment of the present invention, the thickness of the silicon dioxide isolation layer 104 is approximately 300 angstroms (Å). The silicon dioxide layer 104 divides the P type silicon layer 101 into an upper and lower layer, or a first silicon layer 101a and a second silicon layer 101b, respectively, wherein the thickness of the first silicon layer 101a is approximately 1 micrometer. The thickness of the silicon dioxide layer 104 should be as thin as possible but is not fixed at 300 angstrom, changing according to both the manufacturing process and product specifications. Generally speaking, the thickness of the silicon dioxide layer 104 is approximately 50 to 400 angstroms. A 1000° C. annealing process is later used on the surface of the first silicon layer 101a bombarded by the oxygen ions.

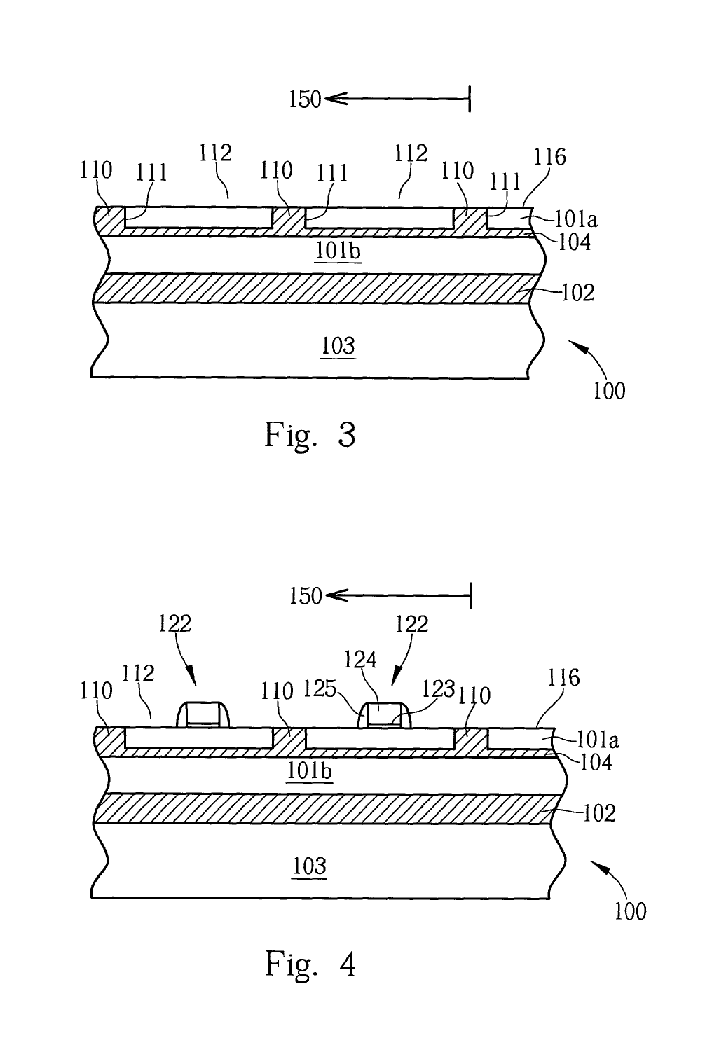

Thereafter, as shown in FIG. 3, a shallow trench isolation (STI) process is used to form the STI 110 in the first silicon layer 101a. The STI 110 functions in simultaneously defining the active area 112 of each DRAM unit within the DRAM memory region 150, and a nearby region 116. A photo and reactive ion etching (RIE) process is applied to the STI 110 to form a shallow trench 111 in the first silicon layer 101a. Then, a silicon dioxide layer can be used as an etching stop layer followed by the filling of the shallow trench 111 with an isolation material, such as silicon dioxide or high-density plasma oxide(HDP oxide. Finally, a chemical-mechanical-polishing (CMP) process is used to complete the manufacturing of STI 110.

As shown in FIG. 4, a plurality of nearly parallel-aligned word lines 122 are formed on the surface of the first silicon layer 101a in the DRAM memory cell area 150 of the DRAM unit. The gate electrodes of the DRAM cell are the regions where the word lines 122 contact the active regions 112. The word line 122 is comprised of a gate oxide layer 123 and a doped polysilicon layer 124, respectively, and each of the side walls of the word line 122 has a spacer 125 comprised of silicon dioxide or silicon nitride. In another preferred embodiment, the word line 122 comprises another self-aligned silicide (salicide) layer (not shown) above the doped polysilicon layer 124 to lower the resistance of the word line 122. The word line 122 is formed by applying the conventional photo, etching and chemical vapor deposition (CVD) processes, and since these processes are obvious to those of ordinary skill in the art, they won't be explained further.

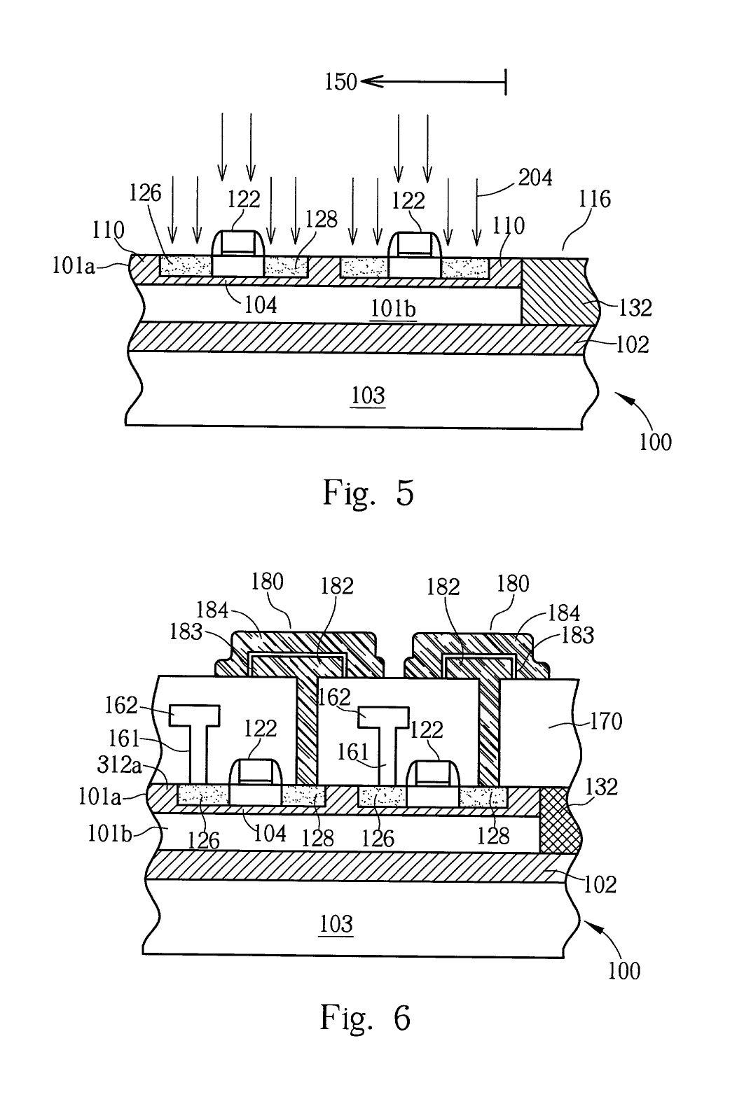

Thereafter, as shown in FIG. 5, a N⁺ ion implantation process is performed on the surface of the first silicon layer 101a in the DRAM memory cell area 150, to form a drain region 126 and a source region 128 on either side of the word line 122, in the DRAM memory cell area 150 in the first silicon layer 101a. When performing the N⁺ ion implantation process on the memory area 150 in the first silicon layer 101a, a photoresist layer can be applied to cover the areas outside the memory regions 150. Then, a P type well pick-up 132 is formed inside an area 116 to connect with the second silicon layer 101b. The method of forming the P type well pick-up 132 is to first manufacture a hole 101b (not shown) inside the area 116, followed by the use of a P⁺ ion implantation process on the polysilicon material filled in the hole to complete the P well pick-up 132.

Finally as shown in FIG. 6, a bit line 162 is formed above the drain region 126 in the dielectric layer 170, and is electrically connected to the drain region 126 through a bit line contact plug 161. Then, a capacitor 182 is formed above the source region 128 and is electrically connected to the source region 128 through a lower storage node 182. The capacitor 180 further comprises a capacitor dielectric layer 183 and an upper electrode 184. The manufacturing method of both the capacitor 180 and the bit line 162 is obvious to those of ordinary skill in the art so will not be explained further.

In another preferred embodiment of the present invention, the silicon layer 101 can be N type. In this case, the drain region 126 and the source region 128 are both P type and the well pick-up 132 is N type.

In contrast to the prior art DRAM device formed on the SOI substrate, the present invention applies an oxygen ion implantation process to form an isolation layer 104 within the silicon layer 101, dividing the silicon layer 101 into an upper and a lower layer (the first silicon layer 101a and the second silicon layer 101b, respectively). The second silicon layer 101b is electrically connected to a bias voltage, which provides a back gate voltage through the well pick-up 132. The result is an effective control of the gate threshold voltage and an improvement in channel control.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a SOI device with high threshold voltage, the method comprising:
providing a silicon-on-insulator (SOI) substrate, the SOI substrate comprising a first isolation layer formed on the substrate, and a first silicon layer with a first conductive type formed on the first isolation layer;
performing an oxygen ion implantation process to form a second isolation layer within the first silicon layer, dividing the first silicon layer into an upper and a lower layer, or a second silicon layer and a third silicon layer, respectively;
forming a shallow trench isolation in the second silicon layer, and forming an active area isolated by the shallow trench isolation with the second isolation layer on the second silicon layer; and
forming at least one metal-oxide-semiconductor field-effect-transistor (MOSFET) in the active area of the second silicon layer, the MOSFET comprising a gate installed on the second silicon layer, and a source and drain region of a second conductive type on each side of the gate electrode in the second silicon layer;
wherein the third silicon layer is electrically connected to a bias voltage power supply through a well pick-up of a first conductive type, to lift the threshold voltage of the gate.

2. The method of claim 1 wherein the first isolation layer is formed by applying a SIMOX process or a thermal oxidation process.

3. The method of claim 1 wherein the thickness of the second isolation layer is approximately 50 to 400 angstroms.

4. The method of claim 1 wherein the thickness of the second silicon layer is approximately 1 micrometer.

5. The method of claim 1 wherein the first conductive type is P type, and the second conductive type is N type.

6. The method of claim 1 wherein the MOSFET further comprises a gate dielectric formed between the gate electrode and the second silicon layer, to induce a channel below the gate electrode dielectric in the second silicon layer.

7. The method of claim 1 wherein the substrate is a silicon substrate.

8. A method of forming a dynamic random access memory (DRAM) unit, the method comprising:
providing a silicon-on-insulator (SOI) substrate, the SOI substrate comprising a first isolation layer formed on a substrate, and a first silicon layer with a first conductive type formed on the first isolation layer;
performing an oxygen ion implantation process to form a second isolation layer within the first silicon layer, the second isolation layer dividing the first silicon layer into an upper and a lower layer, or a second silicon layer and a third silicon layer, respectively;
forming a shallow trench isolation in the second silicon layer, and forming at least one cell array in the active area of the DRAM unit isolated by the shallow trench isolation, with the second isolation layer on the second silicon layer; and
forming a gate electrode on the second silicon layer and a source and drain electrode of a second conductive type in the second silicon layer in the active areas of each DRAM unit;
wherein the source and the drain electrode electrically connect to a bit line and a capacitor, respectively, and the third silicon layer electrically connects to a biased power supply through a well pick-up of a first conductive type, to lift the threshold voltage of the gate electrode;

9. The DRAM unit of claim 8 wherein the first isolation layer is formed by the use of the separation by implanted oxygen (SIMOX) process or a thermal oxidation process.

10. The DRAM unit of claim 8 wherein the thickness of the second isolation layer is approximately 50 to 400 angstroms.

11. The DRAM unit of claim 8 wherein the thickness of the second silicon layer is approximately 1 micrometer.

12. The DRAM unit of claim 3 wherein the first conductive type is P type, and the second conductive type is N type.

13. The DRAM unit of claim 8 wherein the MOSFET further comprises a gate dielectric formed between the gate electrode and the second silicon layer, to induce a channel below the gate electrode dielectric in the second silicon layer.

14. The DRAM unit of claim 8 wherein the substrate is a silicon substrate.
